(19) United States
(12) Patent Application Publication
(10) Pub. No.: US 2007/0126007 A1
(43) Pub. Date: Jun. 7, 2007

(54) SiC semiconductor device and method of fabricating same

(76) Inventor: Kevin Sean Matocha, Rexford, NY (US)

Correspondence Address: Patrick S. Yoder;FLETCHER YODER, P.O. Box 692289, Houston, TX, 77269-2289, US

(21) Appl. No.: 11/295,915

(22) Filed: Dec. 7, 2005

(51) Int. Cl. H01L 31/0312

(52) U.S. Cl. 257/77

(57) ABSTRACT

A SiC semiconductor device and method of fabricating a SiC semiconductor device is provided. The method includes forming a source region and a drain region over a silicon carbide layer which is activated at a high temperature. A gate oxide layer is formed over the silicon carbide layer and is ion-implanted with an atomic species. In another method the gate oxide layer has a thickness of less than about 200 nm.

### BACKGROUND

The invention relates generally to semiconductor devices and in particular to silicon carbide semiconductor devices.

Silicon carbide (SiC) is a wide band gap semiconductor with intrinsic properties that are suited for high power, high temperature and high frequency operation. In addition, SiC is the only known wide band gap semiconductor that has silicon dioxide (SiO₂) as its native oxide. This property makes SiC desirable for the fabrication of metal oxide semiconductor field effect transistors (MOSFETs). SiC can be thermally oxidized to form a gate oxide including SiO₂.

However, the development of SiC MOSFETs has been impeded by a low effective carrier mobility in the FET channel. The low mobility is directly linked to interface defects that either trap or scatter carriers. The low interface state density between the dielectric and semiconductor may result in low on-resistance and low leakage current for a MOSFET. Therefore, there is a need to address these issues to enhance the carrier mobility of SiC based MOSFETs.

Accordingly, a technique is needed to address one or more of the foregoing problems in semiconductor devices, such as SiC MOSFET devices.

### BRIEF DESCRIPTION

In accordance with one embodiment, a method of fabricating a silicon carbide semiconductor device is provided. The method includes forming a source region and a drain region on a silicon carbide layer which is then subjected to a temperature greater than about 1400° C. A gate oxide layer is formed on the silicon carbide layer and is ion-implanted with an atomic species.

In accordance with another embodiment, a silicon carbide MOSFET device is provided. The device includes a source region and a drain region on at least one silicon carbide layer. A gate oxide layer with a thickness of less than about 200 nm is provided on the at least one silicon carbide layer. The gate oxide layer is ion-implanted with an atomic species. Non-limiting examples of atomic species include one or more of nitrogen, boron, phosphorus, cobalt, iron, manganese, chromium, titanium, and nickel.

### DRAWINGS

These and other features, aspects, and advantages of the present invention will become better understood when the following detailed description is read with reference to the accompanying drawings in which like characters represent like parts throughout the drawings, wherein:

FIG. 1 is a flow chart depicting a method of fabricating a SiC MOSFET device according to one embodiment of the invention;

FIG. 2 is a cross-sectional view of a lateral SiC MOSFET device in accordance with an exemplary embodiment of the invention;

FIG. 3 is a cross-sectional view of a vertical SiC MOSFET device in accordance with another embodiment of the invention; and

FIG. 4 is a cross-sectional view of yet another vertical SiC MOSFET device in accordance with yet another embodiment of the invention.

### DETAILED DESCRIPTION

One of the foregoing problems associated with a SiC MOSFET device has been the channel mobility. Embodiments of the present invention address this issue. A gate oxide layer having a thickness of less than about 200 nm is achieved by forming the gate oxide subsequent to formation of source and drain of a MOSFET, in accordance with one embodiment. The thin gate oxide is further ion-implanted. Ion-implantation decreases the interface state density at an interface between the SiC and the gate oxide while improving channel mobility. The low interface state density at the interface between the SiC and the gate oxide may result in low on-resistance and low leakage current for a MOSFET. As described further below, embodiments of the present invention provide improved SiC MOSFET devices.

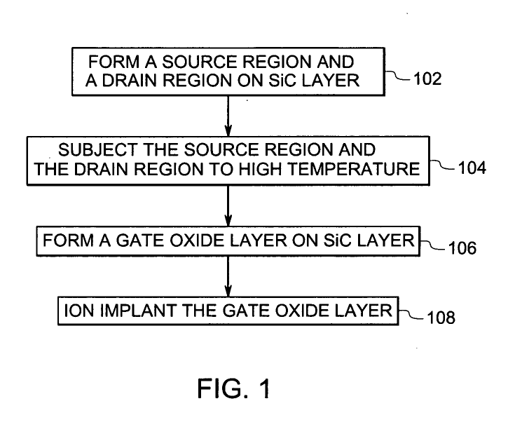

FIG. 1 is a flow chart providing a method 100 to form a silicon carbide based metal oxide field effect transistor (MOSFET), in accordance with one exemplary embodiment. A substrate including silicon carbide (SiC) is provided. The substrate may further include a plurality of layers of SiC. The plurality of layers may be doped to form layers having differing conductivity. At step 102, a source region and a drain region are formed on the SiC layer. The source region and the drain region are differently doped than the underlying SiC layer. For instance, the SiC layer may be p-doped while the source region and the drain region may be n-doped. Optionally, the SiC layer may be n-doped while the source region and the drain region are p-doped. In one embodiment, the source region and the drain region are formed by ion-implantation. In yet another embodiment, the source and drain regions are epitaxially grown on the SiC layer.

Subsequent to the formation of source and drain regions, the source and drain regions are subjected to high temperature, at step 104. High temperature exposure after formation of the source and drain regions may provide certain advantages. For instance, for the source and drain region formed by ion-implantation, exposure to high temperature helps for example, in the electrical activation of ion-implanted species. In another example, source and drain regions are formed by epitaxial growth, through a chemical vapor deposition technique for example, the epitaxial growth is performed at high temperature in step 104. Regardless of the formation techniques employed, high temperature processing is generally employed thereafter. As used herein, “high temperature processing” generally refers to processing at temperatures greater than about 1400° C., and more specifically, in a range of about 1400° C. to about 1700° C.

At step 106, a gate oxide layer is formed. The formation, in one example, is through thermal oxidation of the SiC followed by annealing at high temperature. In another example, a low temperature chemical vapor deposition (CVD) technique is used to form a thin oxide layer. The gate oxide comprises silica (SiO₂) or any other glass forming materials. Non-limiting examples of glass forming materials include borosilicate glass or phosphosilicate glass. In this method, the gate oxide layer is formed after the formation of the source region and the drain region resulting in the formation of a thin layer of oxide, as described further below.

In conventional processing techniques, described in many references, such as “Srideven at al., IEEE Electron device letters, Volume 19, No. 7, pp 228-230”, a thick sacrificial oxide layer is typically deposited on the SiC layer over which source and drain regions are patterned. The thick sacrificial oxide layer is subjected to high temperature for annealing the source region and the drain region. Further, the thick sacrificial oxide layer may be etched, and in some cases, a thin oxide layer is again deposited on the thick oxide layer to form a gate oxide. Disadvantageously, the resulting gate oxide formed in accordance with these conventional techniques is thick and may even be damaged due to the number of steps of processing involved in the formation of gate oxide. Additionally, since the gate oxide is present on the sample prior to source and drain implant activation, the implant activation must be performed at temperature less than about 1400° C.

In contrast, the thickness of the gate oxide layer formed in accordance with embodiments of the present invention may be advantageously thin, generally less than about 200 nm. In one embodiment, the thickness of the gate oxide layer is in a range from about 20 nm to about 200 nm. In another embodiment, the thickness of the gate oxide layer is less than about 20 nm. In yet another embodiment, the thickness of the gate oxide layer is in a range from about 10 nm to about 20 nm.

At step 108, the gate oxide layer is ion-implanted with an atomic species. Advantageously, ion-implantation of the gate oxide layer improves the channel mobility by decreasing the interface state density at an interface of the SiC and the gate oxide layer. Non-limiting examples of atomic species for ion-implantation include one or more of nitrogen, boron, phosphorus, cobalt, iron, manganese, chromium, titanium, cobalt, and nickel. In one embodiment, the dose of implanted atomic species is greater than about 10¹² cm⁻². In another embodiment, the implant dose of atomic species is in the range from about 10¹² cm⁻² to about 10¹⁵ cm⁻². Typical energies used for ion-implantation are in a range from about 15 eV to about 80 eV.

As will be appreciated, in accordance with conventional fabrication techniques, channel mobility was typically improved by annealing the gate oxide in a nitrous oxide or nitric oxide ambient. However, the concentration of nitrogen in the gate oxide obtained using these conventional methods is typically very low. Advantageously, by employing ion-implantation in accordance with the present techniques, high concentrations of atomic species in the gate oxide may be achieved.

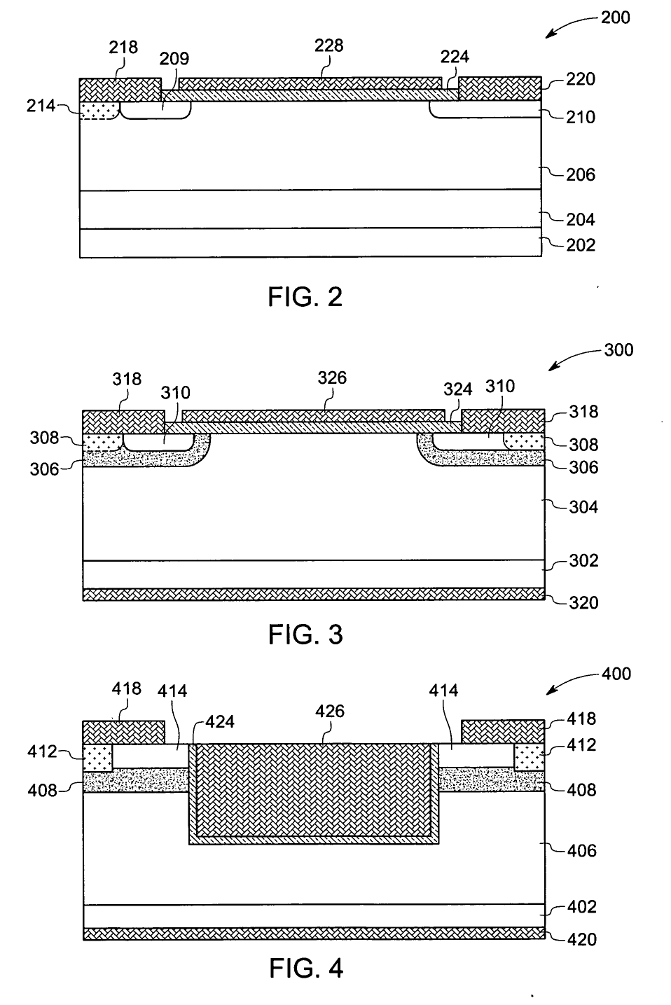

Referring now to FIG. 2, a lateral MOSFET device 200 in accordance with one exemplary embodiment of the present invention is illustrated. The device 200 includes a substrate 202 comprising n-doped SiC. The device 200 includes an n-doped layer 204 which may be epitaxially grown on the substrate 202. The n-doped layer 204 has a carrier concentration in a range of about 10¹⁶ cm⁻³ to about 10¹⁹ cm⁻³. A p-doped SiC layer 206 is provided on the n-doped layer 204. The layer 206 is p-doped with carrier concentrations of about 10¹⁵ cm⁻³ to about 10¹⁷ cm⁻³. The p-doped layer 206 may be formed for example, by epitaxial growth or by ion-implantation. Exemplary techniques for forming p-doped regions may include aluminum or boron implantation.

Heavily n-doped regions 209 and 210 are formed in the p-doped layer 206. As will be appreciated, the n-doped regions or wells 209, 210 may be formed by exposing the n-doped regions 209, 210 to ion-implantation through openings in a mask or masking layer (not shown) which covers the rest of the p-doped layer 206. Suitable atomic species for forming the n-doped regions include nitrogen or phosphorus. Typical carrier concentrations of the n-doped regions 209 and 210 are typically in a range of about 10¹⁸ cm⁻³ to about 10²¹ cm⁻³. A region 214, adjacent to n-doped region 209, is ion-implanted to form highly doped p+ region. Typical carrier concentrations of the p+ region 214 is in a range of about 10¹⁸ cm⁻³ to about 10²¹ cm⁻³. The p+ region 214 may be formed through the process discussed with reference to n-doped regions 209, 210. Following ion-implantation, the implants are activated at a high temperature in the range of about 1400° C. to about 1700° C. The regions 214 and 209 form the source of the device 200, and the region 210 forms the drain of the device 200.

In one embodiment, a source contact 218 is disposed on the source region 214, 209, and a drain contact 220 is disposed on the drain region 210. The deposition and formation of the source and drain contacts 218 and 220 may be achieved through conventional metallization and patterning techniques, as will be appreciated by one skilled in the art. Suitable contact materials include but are not limited to Ni, Ti, Al or an alloy of these. After deposition and patterning, the metal contacts 218 and 220 are annealed at high temperature.

A thin gate oxide layer 224 is formed on the p-doped SiC layer 206. In one embodiment, the formation of the gate oxide layer 224 is through thermal oxidation of the underlying p-doped SiC layer 206. In another embodiment, a low temperature CVD technique is used to form the thin gate oxide layer 224. In one embodiment, the thickness of the gate oxide layer 224 is in a range from about 20 nm to about 200 nm. The gate oxide 224 is then subjected to ion-implantation. In one embodiment, nitrogen ions are implanted with an implantation energy level of about 40 eV. In one embodiment, the dose of the implanted nitrogen is about 10¹³ cm⁻². Advantageously, the nitrogen ion-implantation improves the channel mobility by reducing the interface state density at an interface between the gate oxide layer 224 and the SiC layer 206. A gate contact 228 is disposed on the gate oxide layer 224. Suitable gate contact materials include metals and phosphorus doped polysilicon.

In FIG. 3, a vertical MOSFET device 300, in accordance with another embodiment is shown. The device 300 includes a drift layer 304 formed over an optional SiC substrate 302. The drift layer 304 and the substrate 302 may be of n-doped SiC. In one embodiment, the drift layer 304 is epitaxially grown on the substrate 302. A p-doped region 306 is formed in the drift layer 304 using ion-implantation through a mask or masking layer (not shown). In one embodiment, atomic species for ion-implantation include aluminum or boron. Typical concentrations of ions in the p-doped region 306 are in a range from about 10¹⁶ cm⁻³ to about 5×10¹⁸ cm⁻³. A p+ doped region 308 is formed in the p-doped region 306. In one exemplary embodiment, aluminum is used for ion-implantation to form the p+ doped region 308 having a high carrier concentration. Typical carrier concentrations of the p+ doped region 308 are in the range from about 10¹⁸ cm⁻³ to about 10²¹ cm⁻³. A n+ doped region 310 is formed adjacent to the p+ doped region 308. In one example, the n+ doped region 310 is formed by ion-implanting one or more of nitrogen or phosphorus. Typical carrier concentrations of the n+ doped region 310 are in the range from about 10¹⁸ cm⁻³ to about 10²¹ cm⁻³. Following ion-implantation, the implants are subjected to high temperature. In one embodiment, the implants are activated at a temperature of about 1650° C.

A gate oxide layer 324 is formed over the doped regions 308 and 310 and the p-doped region 306. In one embodiment, the thickness of the gate oxide layer 324 is less than about 200 nm. In one embodiment, the formation of the gate oxide layer 324 is through thermal oxidation of SiC. In another embodiment, a low temperature CVD technique is used to form the thin gate oxide layer 324.

The gate oxide layer 324 is subjected to ion-implantation. The ion-implantation improves the channel mobility of the MOSFET. In one example, the gate oxide layer 324 is nitrogen ion-implanted with a dose of about 10¹³ cm⁻².

Although, the applicants do not wish to be bound by any particular theory, it is believed that the nitrogen forms strong bonds with loose or dangling silicon bonds at the gate oxide/SiC interface and reduces interface state density at the interface of the SiC/gate oxide, and in turn increases the channel mobility. Non-limiting examples of atomic species for ion-implantation include one or more of nitrogen, boron, phosphorus, cobalt, iron, manganese, chromium, titanium, cobalt, and nickel.

Following gate oxide formation, a source contact 318 is provided over the doped region 308 and 310, and a drain contact 320 is provided on the lower side of the substrate 302. The n+ doped region 310 overlaps the gate oxide layer 324 and the source contact 318 to form the source region. Formation of the source and drain contacts 318 and 320 is achieved through conventional metallization and patterning techniques, as will be appreciated by one skilled in the art. In one embodiment, the source and drain contacts 318 and 320 are formed prior to formation of the gate oxide layer 324. Suitable source and drain contacts include Ni, Al, Ti or an alloy of these. A gate contact 326 is provided on the gate oxide layer 324. In one example the gate contact 326 is of phosphorus doped polysilicon. The contacts are then subjected to high temperature.

A vertical MOSFET device 400, in accordance with another exemplary embodiment is shown in FIG.4. The device 400 includes a substrate 402 of SiC. The device 400 includes a drift layer 406, thermally grown over the substrate 402. The substrate 402 and the drift layer 406 are n-doped, with lower charge carrier density in the drift layer 406, with charge carrier densities in the range of about 10¹⁴ cm⁻³ to about 10¹⁶ cm⁻³. P-doped regions 408 and 412 are formed on the drift layer 406 with higher charge carrier density at the p-doped region 412. The p-doped region 412 is doped with carrier concentrations of about 10¹⁸ cm⁻³ to about 10²¹ cm⁻³. The p-doped regions 408 and 412 are formed for example, by ion-implantation. A n-doped region 414 is formed adjacent to p-doped region 412 and forms source region of the device 400. The n-doped region 414 is formed by ion-implantation in one example, with nitrogen. In one embodiment, the carrier concentrations of the n-doped region 414 are in the range from about 10¹⁸ cm⁻³ to about 10²¹ cm⁻³. Typical energy of ion-implantation is about 40 eV. Following ion-implantation, the doped regions 408, 412 and 414 are subjected to high temperature in the range from about 1500° C. to about 1700° C.

A gate oxide layer 424 is formed by etching layer 406 to form a well, and along the sides of the well a thin gate oxide 424 is disposed. The thin gate oxide layer 424 is formed by thermal oxidation of SiC. In one embodiment, the thickness of the gate oxide layer 424 is in a range from about 20 nm to about 90 nm. The gate oxide layer 424 comprises silica and other glass forming materials. Non-limiting examples of glass forming materials include borosilicate glass and phosphosilicate glass. Subsequent to the formation of the gate oxide layer 424, the gate oxide layer 424 is subjected to ion-implantation with suitable atomic species. In one embodiment, the gate oxide layer 424 is implanted with nitrogen at an energy level of about 40 eV. In one embodiment, the dose of the implanted nitrogen is in a range from about 10¹² cm⁻² to about 10¹⁵ cm⁻². A source contact 418, a drain contact 420 and a gate contact 426 are formed as shown in FIG. 4.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A method comprising:
forming a source region and a drain region over a silicon carbide layer;
subjecting the source region and the drain region to a temperature greater than about 1400° C.;
subsequently, forming a gate oxide layer over the silicon carbide layer; and
ion-implanting an atomic species into the gate oxide layer.

2. The method of claim 1 further comprising ion-implanting the atomic species in the source region and the drain region.

3. The method of claim 1, wherein the atomic species implanted into the gate oxide layer comprises nitrogen, or boron, or phosphorus, or cobalt, or iron, or manganese, or chromium, or titanium, or cobalt, or nickel or any combinations thereof.

4. The method of claim 1, wherein a dose of ion-implanted atomic species is greater than about 10¹² cm⁻².

5. The method of claim 1, wherein a dose of ion-implanted atomic species is in a range of about 10¹² cm⁻² to about 10¹⁵ cm⁻².

6. The method of claim 1, wherein subjecting the source region and the drain region to a high temperature comprises subjecting the source region and the drain region to a temperature which is in a range of about 1400° C. to about 1700° C.

7. The method of claim 1, wherein forming the gate oxide layer comprises forming an oxide layer of thickness of less than about 200 nm.

8. The method of claim 1, wherein forming the gate oxide layer comprises forming an oxide layer of thickness in a range of about 20 nm to about 200 nm.

9. The method of claim 1, wherein forming the gate oxide layer comprises forming an oxide layer of thickness of less than about 20 nm.

10. The method of claim 1, wherein forming the gate oxide layer comprises thermally oxidizing the silicon carbide layer or depositing the gate oxide layer over the silicon carbide layer.

11. The method of claim 1 further comprising forming a source contact, a drain contact, and a gate contact.

12. The method of claim 11, wherein forming the gate contact comprises, depositing one or more of a metal, or a phosphorus doped polysilicon or any combinations thereof.

13. A method comprising:
forming a source region and a drain region over a silicon carbide layer;
subjecting the source region and the drain region to a temperature greater than about 1400° C.;
subsequently, forming a gate oxide layer, wherein a thickness of the gate oxide layer is less than about 200 nm; and
ion-implanting an atomic species into the gate oxide layer.

14. The method of claim 13 further comprising ion-implanting an atomic species in the source region and the drain region.

15. The method of claim 13, wherein the atomic species implanted into the gate oxide layer comprises nitrogen, or boron, or phosphorus, or cobalt, or iron, or manganese, or chromium, or titanium, or nickel or any combinations thereof.

16. The method of claim 13, wherein a dose of ion-implanted atomic species is greater than about 10¹² cm⁻².

17. The method of claim 13, wherein a dose of ion-implanted atomic species is in a range of about 10¹² cm⁻² to about 10¹⁵ cm⁻².

18. The method of claim 13, wherein subjecting the source region and the drain region to a high temperature comprises subjecting the source region and the drain region to a temperature which is in a range of about 1400° C. to about 1700° C.

19. The method of claim 13, wherein forming the gate oxide layer comprises thermally oxidizing the silicon carbide layer or depositing the gate oxide layer over the silicon carbide layer.

20. The method of claim 13, wherein a thickness of the gate oxide layer is in a range of about 20 nm to about 200 nm.

21. The method of claim 13, wherein a thickness of the gate oxide layer is less than about 20 nm.

22. The method of claim 13 further comprising forming a source contact, a drain contact, and a gate contact.

23. The method of claim 22, wherein forming the gate contact comprises, depositing one or more of a metal, or a phosphorus doped polysilicon or any combinations thereof

24. A silicon carbide MOSFET device comprising:
at least one silicon carbide layer;
a source region and a drain region formed on the at least one silicon carbide layer;
a gate oxide layer disposed over the at least one silicon carbide layer,
wherein the gate oxide layer is ion-implanted with an atomic species, the atomic species comprising nitrogen, boron, phosphorus, cobalt, iron, manganese, chromium, titanium, nickel or any combinations thereof; and
wherein a thickness of the gate oxide layer is less than about 200 nm.
